(19) United States
(12) Patent Application Publication
(10) Pub. No.: US 2026/0088816 A1
(43) Pub. Date: Mar. 26, 2026

(54) DRIVE DETECTION CIRCUIT AND DRIVE DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Daisuke ARAI, Kawasaki Kanagawa (JP); Koji Sato, Yokohama Kanagawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/042,097

(22) Filed: Jan. 31, 2025

(30) Foreign Application Priority Data
Sep. 20, 2024 (JP) 2024-163837

(51) Int. Cl. H03K 17/687

(52) U.S. Cl. CPC H03K 17/6871; H03K 2217/0027; H03K 2217/0063; H03K 2217/0072

(57) ABSTRACT

According to one embodiment, a drive detection device includes: a first terminal; a second terminal; a first transistor having a first end connected to the first terminal, a second end connected to a first node, and a control end connected to the second terminal; a second transistor having a first end connected to the second terminal, a second end connected to a second node, and a control end connected to the first terminal; a first current mirror circuit having an input end connected to the first node and an output end connected to the second node; a current source having an input end connected to the second node; and a third transistor having a control end connected to the second node.

### CROSS-REFERENCE TO RELATED APPLICATIONS

This application is based upon and claims the benefit of priority from Japanese Patent Application No. 2024-163837, filed Sep. 20, 2024, the entire contents of which are incorporated herein by reference.

### FIELD

Embodiments described herein relate generally to a drive detection circuit and a drive device.

### BACKGROUND

There has been known a drive device that drives transistors to control a motor or the like, and a drive detection circuit that is provided in the drive device and that detects driving of the transistors.

### BRIEF DESCRIPTION OF THE DRAWINGS

FIG. 1 is a block diagram illustrating a first example of a configuration of a motor drive system including a drive device according to an embodiment.

FIG. 2 is a block diagram illustrating a second example of a configuration of the motor drive system including the drive device according to the embodiment.

FIG. 3 is a circuit diagram illustrating an example of a configuration of a drive detection circuit of the drive device according to the embodiment.

### DETAILED DESCRIPTION

In general, according to one embodiment, a drive detection circuit includes: a first terminal; a second terminal; a first transistor having a first end connected to the first terminal, a second end connected to a first node, and a control end connected to the second terminal; a second transistor having a first end connected to the second terminal, a second end connected to a second node, and a control end connected to the first terminal; a first current mirror circuit having an input end connected to the first node and an output end connected to the second node; a current source having an input end connected to the second node; and a third transistor having a control end connected to the second node.

Hereinafter, embodiments will be described with reference to the drawings. In the following description, components having substantially identical function and configuration are given the same reference numeral. In a case where the elements having similar configuration are to be specifically distinguished from each other, mutually different characters or numbers may be added to the end of the same reference numeral.

### 1. Configuration

### 1.1 Drive Device

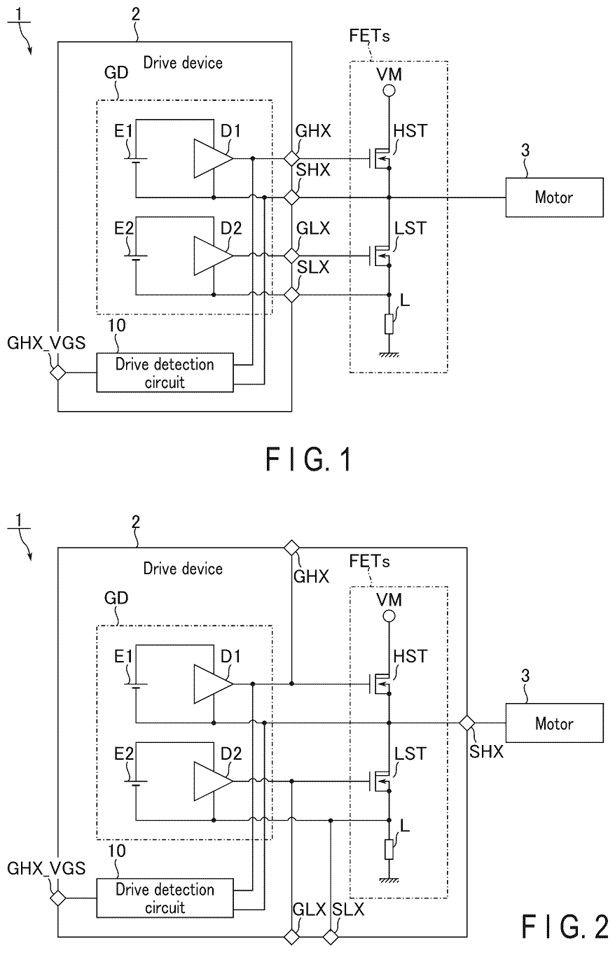

FIG. 1 is a block diagram illustrating a first example of a configuration of a motor drive system including a drive device according to an embodiment. FIG. 2 is a block diagram illustrating a second example of a configuration of the motor drive system including the drive device according to the embodiment. A motor drive system 1 includes a drive device 2, a transistor group FETs and a motor 3. The motor drive system 1 is an application that executes predetermined operations with the use of a torque obtained from the motor 3.

As illustrated in FIG. 1, the transistor group FETs may be externally connected to the drive device 2. As illustrated in FIG. 2, the transistor group FETs may be built into the drive device 2.

The drive device 2 is, for example, an integrated circuit (IC) chip that functions as a motor control driver (MCD). The drive device 2 drives the transistor group FETs, for example, in accordance with a control signal from a not-shown micro controller unit (MCU) or the like. As the transistor group FETs are driven, the drive device 2 can control the motor 3. Specifically, the drive device 2 includes a gate driver GD and terminals GHX, SHX, GLX and SLX. The gate driver GD includes power supplies E1 and E2, and drivers D1 and D2.

The driver D1 has an output end connected to the terminal GHX. The voltage output from the driver D1 is, for example, a high voltage of 40 V or higher. The power supply E1 drives the driver D1 by generating a potential difference of about 12 V, for example. A low potential side of the power supply E1 is connected to the terminal SHX.

The driver D2 has an output end connected to the terminal GLX. The power supply E2 drives the driver D2 by generating a potential difference of about 12 V, for example. A low potential side of the power supply E2 is connected to the terminal SLX.

The transistor group FETs includes transistors HST and LST, and a load L. The transistors HST and LST are, for example, field effect transistors with N-type conductivity.

The transistor HST has a first end to which a voltage VM is supplied, a second end connected to the terminal SHX, and a control end connected to the terminal GHX. The transistor HST is configured to have a high breakdown voltage sufficient to be able to stably operate even under a high voltage supplied from the terminal GHX. Hereinafter, the transistor having the high breakdown voltage sufficient to be able to stably operate even under the high voltage supplied from the terminal GHX is also referred to as a “high breakdown voltage transistor” in contrast to normal transistors that operate at a voltage of a few volts.

The transistor LST has a first end connected to the terminal SHX, a second end connected to the terminal SLX, and a control end connected to the terminal GLX. The load L has a first end connected to the terminal SLX and a second end being grounded. In this manner, the transistors HST and LST, and the load L are connected in series in this order between the supply source of the voltage VM and the ground. Hereinafter, the transistors HST and LST are also referred to as “a high-side transistor” and “a low-side transistor,” respectively.

In the above-described configuration, the gate driver GD controls drive states (that is, on state and off state) of the transistors HST and LST by applying an appropriate voltage to each gate of the transistors HST and LST. The motor 3 is connected to a node (that is, the terminal SHX) that connects the transistors HST and LST. With this configuration, the gate driver GD can drive the motor 3 through the transistor group FETs.

The drive device 2 further includes a drive detection circuit 10 and a terminal GHX_VGS. The drive detection circuit 10 is a circuit for detecting whether the transistor HST is in the on state or in the off state. The drive detection circuit 10 is connected to the terminals GHX, SHX and GHX_VGS. The drive detection circuit 10 detects, on the basis of voltages at the terminals GHX and SHX, whether the transistor HST is in the on state or in the off state. Then, the drive detection circuit 10 outputs a signal indicating a detection result to the terminal GHX_VGS.

In the examples in FIGS. 1 and 2, there is shown a case in which the motor drive system 1 has a pair of gate drivers GD, the transistor group FETs, and the drive detection circuit 10 for the single motor 3, but it is not limited to this. For example, the motor drive system 1 may have multiple pairs (for example, three pairs) of gate drivers GD, the transistor group FETs, and the drive detection circuit 10 for the single motor 3. In a case where the motor drive system 1 includes three pairs of gate drivers GD, the transistor group FETs, and the drive detection circuit 10 for the single motor 3, the motor 3 may be able to function as a three-phase AC motor.

In the case where the motor drive system 1 includes multiple pairs of gate drivers GD, the transistor groups FETs, and the drive detection circuit 10 for the single motor 3, the configuration of each of a plurality of drive detection circuits 10 provided in the drive device 2 is equivalent. In the following, an explanation will be given as to the configuration of an any one of the drive detection circuits 10 provided in the drive unit 2.

### 1.2 Drive Detection Circuit

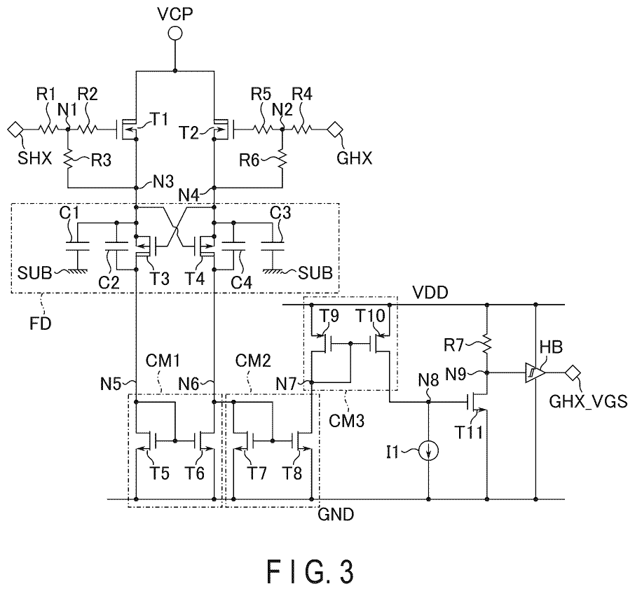

FIG. 3 is a circuit diagram illustrating an example of a configuration of the drive detection circuit of the drive device according to the embodiment.

The drive detection circuit 10 includes a plurality of resistors R, a plurality of transistors T, a current source I1, and a buffer HB. The plurality of resistors R include resistors R1, R2, R3, R4, R5, R6 and R7. The plurality of transistors T include transistors T1, T2, T3, T4, T5, T6, T7, T8, T9, T10 and T11. The transistors T1, T2, T3 and T4 are high breakdown voltage transistors. In contrast, the transistors T5, T6, T7, T8, T9, T10 and T11 are normal transistors.

The resistor R1 has a first end connected to the terminal SHX and a second end connected to a node N1. The resistor R2 has a first end connected to the node N1. The resistor R3 has a first end connected to the node N1 and a second end connected to a node N3.

The transistor T1 is a double-diffused metal oxide semiconductor (DMOS) with the N-type conductivity. The transistor T1 has a first end to which a voltage VCP is supplied, a second end connected to the node N3, and a control end connected to a second end of the resistor R2. The transistor T1 functions as a source follower circuit of the transistor T3.

The voltage VCP is a high voltage equal to or higher than the voltage supplied from the driver D1 to the transistor HST (that is, the voltage applied to the terminal GHX). The voltage VCP is supplied, for example, from a not-shown charge pump circuit in the drive device 2.

The resistor R4 has a first end connected to the terminal GHX and a second end connected to a node N2. The resistor R5 has a first end connected to the node N2. The resistor R6 has a first end connected to the node N2 and a second end connected to a node N4.

The transistor T2 is a DMOS with the N-type conductivity. The transistor T2 has a first end to which the voltage VCP is supplied, a second end connected to the node N4, and a control end connected to a second end of the resistor R5. The transistor T2 functions as a source follower circuit of the transistor T4.

The transistors T3 and T4 are DMOSs with P-type conductivity. The transistor T3 has a first end connected to the node N3, a second end connected to a node N5, and a control end connected to the node N4. The transistor T4 has a first end connected to the node N4, a second end connected to a node N6, and a control end connected to the node N3. The transistors T3 and T4 function as a full differential circuit FD with the node N3 as a first input end, the node N4 as a second input end, the node N5 as a first output end and the node N6 as a second output end.

A capacitor C1 is a parasitic capacitance that occurs between a substrate SUB and a source of the transistor T3. A capacitor C2 is a parasitic capacitance that occurs between the source of the transistor T3 and a drain of the transistor T3.

A capacitor C3 is a parasitic capacitance that occurs between a substrate SUB and a source of the transistor T4. A capacitor C4 is a parasitic capacitance that occurs between the source of the transistor T4 and a drain of the transistor T4.

Incidentally, with each of the transistors T5, T6, T7, T8, T9, T10 and T11 to be described below, a parasitic capacitance between a substrate and a source, and a parasitic capacitance between the source and the drain may occur. However, as described above, because the transistors T3 and T4 are high breakdown voltage transistors, the size thereof is larger than that of the normal transistors T5, T6, T7, T8, T9, T10 and T11. For this reason, in view of high precision detection of a drive state of the transistor HST, while the parasitic capacitances of the normal transistors are small enough to be negligible, the parasitic capacitances of the capacitors C1, C2, C3 and C4 of the high breakdown voltage transistors are large enough not to be negligible. Therefore, in FIG. 3, the capacitors C1, C2, C3 and C4 are deliberately illustrated.

The transistors T5 and T6 are complementary metal oxide semiconductors (CMOSs) with the N-type conductivity. The transistor T5 has a first end and a control end that are connected to the node N5, and a second end grounded to a voltage GND. The transistor T6 has a first end connected to the node N6, a second end grounded to the voltage GND, and a control end connected to the node N5. The voltage GND is a ground voltage (for example, 0 V). The transistors T5 and T6 function as a current mirror circuit CM1 with the node N5 as an input end and the node N6 as an output end.

The transistors T7 and T8 are CMOSs with the N-type conductivity. The transistor T7 has a first end and a control end that are connected to the node N6, and a second end grounded to the voltage GND. The transistor T8 has a first end connected to a node N7, a second end grounded to the voltage GND, and a control end connected to the node N6. The transistors T7 and T8 function as a current mirror circuit CM2 with the node N6 as an input end and the node N7 as an output end. In this way, the output end of the current mirror circuit CM1 and the input end of the current mirror circuit CM2 are connected in parallel to the node N6.

The transistors T9 and T10 are CMOSs with the P-type conductivity. The transistor T9 has a first end and a control end that are connected to the node N7, and a second end to which the voltage VDD is supplied. The transistor T10 has a first end connected to a node N8, a second end to which the voltage VDD is supplied, and a control end connected to the node N7. The voltage VDD is a power supply voltage (for example, several V). The transistors T9 and T10 function as a current mirror circuit CM3 with the node N7 as an input end and the node N8 as an output end.

The current source I1 has an input end connected to the node N8 and an output end grounded to the voltage GND. The current flowing through the current source I1 is associated, via the current mirror circuits CM2 and CM3, with the current flowing through the transistor T7. In this way, although the current source I1 is not electrically connected to the node N6, it may be regarded as being connected via a current buffer circuit configured by the current mirror circuits CM2 and CM3.

The resistor R7 has a first end to which the voltage VDD is supplied and a second end connected to a node N9.

The transistor T11 is a CMOS with the N-type conductivity. The transistor T11 has a first end connected to the node N9, a second end grounded to the voltage GND, and a control end connected to the node N8. In a case where the transistor T11 is in an on state, the voltage at the node N9 decreases so as to approach the voltage GND. In a case where the transistor T11 is in an off state, the voltage at the node N9 increases so as to approach the voltage VDD.

The buffer HB is a hysteresis buffer driven by the voltage VDD. The buffer HB has an input end connected to the node N9 and an output end connected to the terminal GHX_VGS. The buffer HB determines, on the basis of the voltage at the node N9, a drive state of the transistor T11. The buffer HB outputs a determination result of the drive state of the transistor T11 to the terminal GHX_VGS. Specifically, for example, in a case where the voltage at the node N9 is equal to or higher than a threshold value, the buffer HB outputs a “High” level indicating that the transistor T11 is in the off state. In a case where the voltage at the node N9 is less than the threshold value, the buffer HB outputs a “Low” level indicating that the transistor T11 is in the on state. The threshold value is set between the voltages GND and VDD.

With the configuration described above, in the drive detection circuit 10, a potential difference between the terminals GHX and SHX (that is, a potential difference between the gate and the source of the transistor HST) is converted into the current by the transistor T4. By comparing the current flowing through the transistor T4 with the current flowing through the current source I1, the drive state of the transistor T11 is switched. Therefore, by adjusting a condition under which the drive state of the transistor T11 is switched so as to match a condition under which the drive state of the transistor HST is switched, the drive detection circuit 10 can output, to the terminal GHX_VGS, a signal indicating the drive state of the transistor T11 as a signal indicating the drive state of the transistor HST.

More specifically, in a case where the potential difference between the terminals GHX and SHX is large, the current flowing through the transistor T4 increases. As a result, the voltage at the node N8 increases and the transistor T11 is brought into the on state. When the transistor T11 is brought into the on state, the voltage input to the buffer HB decreases. Therefore, the buffer HB can output, to the terminal GHX_VGS, a “Low” level signal indicating that the transistor T11 (and HST) is in the on state.

On the other hand, in a case where the potential difference between the terminals GHX and SHX is small, the current flowing through the transistor T4 decreases. As a result, the voltage at the node N8 drops and the transistor T11 is brought into the off state. When the transistor T11 is brought into the off state, the voltage input to the buffer HB increases. Therefore, the buffer HB can output, to the terminal GHX_VGS, a “High” level signal indicating that the transistor T11 (and HST) is in the off state.

### 2. Effects of Embodiments

According to the embodiments, the transistor T3 has the first end connected to the terminal SHX, the second end connected to the node N5, and the control end connected to the terminal GHX. The transistor T4 has the first end connected to the terminal GHX, the second end connected to the node N6, and the control end connected to the terminal SHX. The current mirror circuit CM1 has the input end connected to the node N5 and the output end connected to the node N6. Thus, the current mirror circuit CM1 can suppress, for example, during the regeneration of the motor 3, an influence of the parasitic current caused by the capacitor C4, which is the parasitic capacitance of the transistor T4, on the driving situation of the transistor T11.

To add, during the regeneration of the motor 3, in a state in which the potential difference between the gate and the source of the transistor HST does not occur (that is, in the state in which the transistor HST is maintained in the off state), the voltages applied to the gate and the source of the transistor HST increase simultaneously. In this case, the parasitic current caused by the capacitor C4 may occur in the drive detection circuit 10. In a case where the parasitic current is included as a target for comparison with the current flowing through the current source I1, there may be a possibility that, due to increase in the voltage applied to the gate of the transistor T11, the transistor T11 is brought into the on state even though the transistor HST is in the off state. In this manner, it is undesirable that the parasitic current caused by the capacitor C4 is included as the target for comparison with the current flowing through the current source I1, because there is a possibility of causing false detection of the on state of the transistor HST.

According to the embodiments, the transistors T3 and T4 constitute the full differential circuit FD. Two output ends of the full differential circuit are connected to the input end and the output end of the current mirror circuit CM1, respectively. With this configuration, the parasitic current caused by the capacitor C2 and the parasitic current caused by the capacitor C4 can be made to flow respectively into the input end and the output end of the current mirror circuit CM1, during the regeneration of the motor 3. Thus, the parasitic current caused by the capacitor C4 can be canceled from the current to be compared with the current source I1. Therefore, the false detection of the on state of the transistor HST during the regeneration of the motor 3 can be suppressed.

The transistor T1 has the first end to which the voltage VCP is supplied, and the second end and the control end that are connected to the terminal SHX. The transistor T2 has the first end to which the voltage VCP is supplied, and the second end and the control end that are connected to the terminal GHX. Namely, the transistors T1 and T2 respectively function as the source follower circuit for the transistors T3 and as the source follower circuit for T4. With this configuration, when the capacitors C1 and C2 are charged in response to the voltage fluctuation at the terminal SHX during the transition from the off state to the on state of the transistor HST, the current required for the charging can be supplied from the supply source of the voltage VCP. Similarly, when the capacitors C3 and C4 are charged in response to the voltage fluctuation at the terminal GHX during the transition from the off state to the on state of the transistor HST, the current required for the charging can be supplied from the supply source of the voltage VCP. Thus, the amount of current flowing into the drive detection circuit 10 via the terminals SHX and GHX can be reduced. Therefore, the load that the drive detection circuit 10 applies to the driver D1 in the drive control of the transistor HST can be reduced.

The current mirror circuits CM2 and CM3 function as a current buffer circuit provided between the node N6 and the node N8. With this configuration, the current source I1 is electrically isolated from the capacitor C4 which is the parasitic capacitance of the transistor T4. Thus, an influence of delay, caused by the capacitor C4, of change in the voltage applied to the gate of the transistor T11 can be reduced. Therefore, the time required for the drive detection circuit 10 to detect the transition of the drive state of the transistor T11 (for example, a transition from the on state to the off state) can be shortened.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A drive detection circuit comprising:
a first terminal;
a second terminal;
a first transistor having a first end connected to the first terminal, a second end connected to a first node, and a control end connected to the second terminal;
a second transistor having a first end connected to the second terminal, a second end connected to a second node, and a control end connected to the first terminal;
a first current mirror circuit having an input end connected to the first node and an output end connected to the second node;
a current source having an input end connected to the second node; and
a third transistor having a control end connected to the second node.

2. The drive detection circuit according to claim 1, further comprising:
a fourth transistor having a first end connected to a power supply, and a second end and a control end that are connected to the first terminal;
a fifth transistor having a first end connected to the power supply, and a second end and a control end that are connected to the second terminal,
wherein the power supply is configured to supply a voltage of equal to or higher than a voltage applied to the second terminal.

3. The drive detection circuit according to claim 2, wherein,
the first transistor and the second transistor have a first conductive type, and
the third transistor, the fourth transistor, the fifth transistor, and the first current mirror circuit have a second conductivity type.

4. The drive detection circuit according to claim 1, further comprising a current buffer circuit provided between the second node, and the current source and the third transistor.

5. The drive detection circuit according to claim 4, wherein the current buffer circuit includes:
a second current mirror circuit having an input end connected to the second node and an output end connected to a third node; and
a third current mirror circuit having an input end connected to the third node and an output end connected to the input terminal of the current source and the control end of the third transistor.

6. The drive detection circuit according to claim 5, wherein
the first transistor, the second transistor, and the third current mirror circuit have a first conductivity type; and
the third transistor, the first current mirror circuit, and the second current mirror circuit have a second conductivity type.

7. The drive detection circuit according to claim 6, wherein
the first current mirror circuit includes:
a sixth transistor having a first end and a control end that are connected to the first node; and
a seventh transistor having a first end connected to the second node and a control end connected to the first node,
the second current mirror circuit includes:
an eighth transistor having a first end and a control end that are connected to the second node; and
a ninth transistor having a first end connected to the third node and a control end connected to the second node; and
the third current mirror circuit includes:
a tenth transistor having a first end and a control end that are connected to the third node; and
an eleventh transistor having a first end connected to the input end of the current source and the control end of the third transistor, and a control end connected to the third node.

8. The drive detection circuit according to claim 1, wherein the first transistor and the second transistor are each a double-diffused metal oxide semiconductor (DMOS).

9. A drive device comprising:
the drive detection circuit according to claim 1, and
a driver configured to output a first voltage to the second terminal.

10. The drive device according to claim 9, wherein the first voltage is equal to or higher than 40V.

11. The drive device according to claim 9, further comprising:
a fourth transistor having a first end connected to a power supply, and a second end and a control end that are connected to the first terminal; and
a fifth transistor having a first end connected to the power supply, and a second end and a control end that are connected to the second terminal,
wherein the power supply is configured to supply a voltage of equal to or higher than a voltage applied to the second terminal.

12. The drive device according to claim 11, wherein
the first transistor and the second transistor have a first conductivity type, and
the third transistor, the fourth transistor, the fifth transistor, and the first current mirror circuit have a second conductivity type.

13. The drive device according to claim 9, further comprising a current buffer circuit provided between the second node, and the current source and the third transistor.

14. The drive device according to claim 13, wherein the current buffer circuit includes:
a second current mirror circuit having an input end connected to the second node and an output end connected to a third node; and
a third current mirror circuit having an input end connected to the third node and an output end connected to the input end of the current source and the control end of the third transistor.

15. The drive device according to claim 14, wherein
the first transistor, the second transistor, and the third current mirror circuit have a first conductivity type; and
the third transistor, the first current mirror circuit, and the second current mirror circuit have a second conductivity type.

16. The drive device according to claim 15, wherein
the first current mirror circuit includes:
a sixth transistor having a first end and a control end that are connected to the first node; and
a seventh transistor having a first end connected to the second node and a control end connected to the first node,
the second current mirror circuit includes:
an eighth transistor having a first end and a control end that are connected to the second node; and
a ninth transistor having a first end connected to the third node and a control end connected to the second node, and
the third current mirror circuit includes:
a tenth transistor having a first end and a control end that are connected to the third node; and
an eleventh transistor having a first end connected to the input end of the current source and the control end of the third transistor, and a control end connected to the third node.

17. The drive device according to claim 9, wherein the first transistor and the second transistors are each a double-diffused metal oxide semiconductor (DMOS).
